(19) United States
(12) Patent Application Publication
(10) Pub. No.: US 2014/0001429 A1
(43) Pub. Date: Jan. 2, 2014

(54) HETEROJUNCTION OXIDE MEMORY DEVICE WITH BARRIER LAYER

(71) Applicant: 4-DS PTY, LTD, Perth (AU)

(72) Inventors: Yue-Song He, San Jose, CA (US); Kurt Pfluger, Monte Serrano, CA (US); Jean Yang-Scharlotta, Glendale, CA (US)

(73) Assignee: 4-DS PTY, LTD, Perth (AU)

(21) Appl. No.: 13/841,147

(22) Filed: Mar. 15, 2013

Related U.S. Application Data
(60) Provisional application No. 61/666,933, filed on Jul. 2, 2012.

(51) Int. Cl. H01L 45/00

(52) U.S. Cl. CPC H01L 45/12; H01L 45/16
USPC 257/2; 438/104

(57) ABSTRACT

A resistive memory device is provided that includes a barrier layer in between two metal oxide layers. The barrier layer prevents free flow of oxygen ions between the two metal oxide layers in order to increase the retention period for the data stored in the memory device.

### CROSS-REFERENCES TO RELATED APPLICATIONS

This application claims the benefit under 35 USC §119(e) to U.S. Provisional Patent Application No. 61/666,933 filed on Jul. 2, 2012, the contents of which are incorporated by reference herein in its entirety for all purposes.

This application is related to U.S. patent application Ser. No. 13/396,404 filed on Feb. 14, 2012, which claims priority under 35 U.S.C. §371 to PCT Application No. PCT/US2010/045667, filed on Aug. 16, 2010, which in turn claims priority to U.S. Provisional Application No. 61/234,183, filed on Aug. 14, 2009. The disclosures of these applications are all incorporated by reference herein in their entirety for all purposes.

### BACKGROUND

As Moore's Law has been predicted, the capacity of memory cells on silicon for the past 15-20 years has effectively doubled each year. Moore's Law roughly states that every year the amount of devices such as transistor gates or memory cells on a silicon wafer will double, thus doubling the capacity of the typical chip while the price will essentially stay the same. As the devices continue to shrink, device technology is starting to reach a barrier known as the quantum limit, that is, they are actually approaching atomic dimensions, so the cells cannot get any smaller.

As a response to the limitations of directly shrinking transistor gates and memory cells, the “More than Moore's Law” movement has taken hold to push beyond simply shrinking cell size to increase the chip functionality. The focus is directed instead on methods to improve system integration as the means to increase the functionality and decrease the size of the final electronics product. For example, system-on-package methods combine individual chips with different functionalities such as microprocessor, microcontroller, sensor, memory, and others in one package rather than connecting them over a printed-circuit board with large discreet passive components. The system-on-package method further addresses sizes of discreet passive components—such as resistors, capacitors, inductors, antennas, filters, and switches by using micrometer-scale thin-film versions of discrete components. Another example is system-on-chip, which seeks to build entire signal-processing systems or subsystems with diverse functions on a chip of silicon—a system-on-chip, or SOC. Such a chip may include digital logic and memory for computation, analog and RF communications circuitry, and other circuit functions. Usually, these dissimilar circuits not only operate at different voltages but also require different processing steps during manufacture. Such differences have traditionally been a barrier to integrating such diverse circuitry on a single chip. For example, the processes for manufacturing microprocessors and flash nonvolatile memory chips are so different that the cost of manufacturing the two types of devices on the same chips is the same or more as the cost of manufacturing the two chips separately. Thus a different type of memory device while can be more easily and economically integrated with digital logic, analog, and RF circuitry is needed.

Separately, disk drives have been a type of information storage which provided a significant portion peak capacity. The storage density provided by disk drives have been cheaper than semiconductor memory devices at least partially due to the way disk drives store and read individual bits of information in individual domains (magnetic transition sites) with an external probe. This method of storing and reading the information does not require individual circuit connections for each bit of storage location, thus requiring significantly less overhead than storage in semiconductor memory which does require the individual circuit connections. The individually connected semiconductor memory such as Flash memory, however, is preferable to disk drives in terms of resistance to shock as it has no moving parts which may be damaged by movement and shock.

As semiconductor device scaling passes 90 nanometer feature size, or node to 45 and 25 nanometer nodes, the semiconductor memory density are beginning to reach similar density and cost as disk drive storage. Multiple bit storage per device, where a multiple of data bits may be stored in a single cell by a division of ranges, has also been employed to increase density and reduce cost.

Semiconductor memories such as flash memory of the floating gate or charge trapping types suffer from other issues due to scaling. As the size of the devices become smaller, variations of a few electrons begin to manifest as large variations in device characteristics such as current, write speed, and erase speed. Such large variations further require increased write, read, and erase time to reach the same distribution ranges for operation and reduce the supportable dynamic ranges for multiple bit storage.

Yet one more concern for traditional flash type of semiconductor memory scaling is the reduction of the number of write/erase cycle the cell will tolerate before it permanently fails. Prior to the substantial reduction in cell size, the typical flash memory write/erase cycle tolerance rating is in the range of 1,000,000, however, as the feature size reduces in size, write/erase cycle tolerance rating has diminished to the range of 3000 cycles. This reduction of write/erase cycle tolerance limits the applications for the memory. For example, for a memory device to also function in current SRAM and DRAM applications, such memory must tolerate data exchange at much higher repetition rates, typically several times per microsecond, resulting in 1,000,000 or more cycles.

Accordingly, what is desired are a memory device, system and method which overcome the above-identified problems. The memory device, system and method should be easily implemented, cost effective and adaptable to existing storage applications. The system and method should also be simple to integrate with other ICs in terms of processing and operating voltages. The present disclosure addresses such a need.

### SUMMARY

The present disclosure relates generally to memory devices, and more particularly to a memory device that includes hetero junction oxide material.

Some embodiments of the present invention disclose a memory device. The memory device comprises a first metal layer and a first metal oxide layer coupled to the first metal layer. The memory device also includes a barrier layer coupled to the first metal oxide layer, a second metal oxide layer coupled to the barrier layer, and a second metal layer coupled to the second metal oxide layer. The formation of the first metal oxide layer has a Gibbs free energy that is lower than the Gibbs free energy for the formation of the second metal oxide layer.

Other embodiments of the present invention provide a memory device that includes a first metal layer, a first metal oxide layer coupled to the first metal layer, a barrier layer coupled to the first metal oxide layer, a second metal oxide layer coupled to the barrier layer, and a second metal layer coupled to the second metal oxide layer. In this embodiment, the Gibbs free energy for the formation of the first metal oxide layer is lower than the Gibbs free energy for the formation of the second metal oxide layer.

In some embodiments, the first metal layer can include Aluminum, Titanium, Tantalum, Gold, Silver, or Platinum. In an embodiment, the first metal oxide layer can include one of Praseodymium Calcium Manganese Oxide (PCMO), Lanthanum Calcium Manganese Oxide (LCMO), Hafnium oxide (HfxOy), Aluminum oxide (AlxOy), or Tantalum oxide (TaxOy). In a particular embodiment, a thickness of the first metal oxide layer is in the range of 50 angstroms to 2000 angstroms. In some embodiments, the first metal oxide layer has a first thickness that is three to five times greater than a second thickness of the second metal oxide layer. In some embodiments, the thickness of the barrier layer is between 5 and 50 angstroms. In an embodiment, the second metal layer comprises an inert metal.

Some embodiments of the present invention provide a memory device. The memory device includes a substrate having a top surface and an opposing bottom surface, a first metal layer coupled to the top surface of the substrate, a Praseodymium Calcium Manganese Oxide (PCMO) layer coupled to the first metal layer, a barrier layer coupled to the PCMO layer, a metal oxide layer coupled to the barrier layer, and a second metal layer coupled to the metal oxide layer. Further, a first Gibbs free energy for the metal oxide layer is lower than a second Gibbs free energy for the PCMO layer.

In some embodiments, the PCMO layer is characterized by a first thickness that is twenty to fifty times greater than a second thickness of the metal oxide layer. In an embodiment, the second thickness is in the range of 10 to 50 angstroms. In some embodiments, the barrier layer is between 10 and 30 angstroms thick. In some embodiments, the first metal layer and the second metal layer includes one of: Aluminum, Titanium, Tantalum, Gold, Silver, or Platinum. In a particular embodiment, the metal oxide layer includes one of TiO₂, Ta₂O₅, NiO, WO₃, or Al₂O₃. In some embodiments, the PCMO layer is characterized by a first state having a first resistance and a second state having a second resistance and the metal oxide layer is characterized by a third state having a third resistance state and a fourth state having a fourth resistance. In this embodiment, the first resistance is higher than the second resistance and the third resistance is higher than the fourth resistance.

Certain embodiments of the present invention provide a method of manufacturing a memory device. The method includes providing a substrate having an upper surface and an opposing lower surface and forming a first metal layer over the upper surface of the substrate. The method further includes forming a first metal oxide layer over the first metal layer, where the first metal oxide layer has a thickness of between 500 and 1000 angstroms. The method also includes forming a barrier layer over the first metal oxide layer, forming a second metal oxide layer over the barrier layer, and forming a second metal layer over the second metal oxide layer. In the method, a first Gibbs free energy for the second metal oxide layer is lower than a second Gibbs free energy for the first metal oxide layer.

In some embodiments, the barrier layer includes a wide bandgap material including one of Aluminum oxide (AlxOy), Hafnium oxide (HfxOy), Nickel oxide (NixOy), or Tantalum oxide (TaxOy). In other embodiments, the second metal oxide layer is spontaneously formed at an interface of the barrier layer and the second metal layer. In a particular embodiment, non-uniformity of the barrier layer is between 1% and 5%. In some embodiments, the first metal oxide layer includes Praseodymium Calcium Manganese Oxide (PCMO). In an embodiment, the thickness of the barrier layer is between 10 and 50 angstroms.

The following detailed description, together with the accompanying drawings will provide a better understanding of the nature and advantages of the present invention.

### BRIEF DESCRIPTION OF THE DRAWINGS

FIGS. 1A and 1B illustrate a memory device in accordance with an embodiment of the present invention.

FIG. 2 is a graph showing resistance versus the Gibbs free energy of oxidation for various metals.

FIG. 3 illustrates a set of transmission electron micrographs (TEM's) that show the cross sections of formation of (or no formation of) metal oxide at the junction of two types of interfaces according to an embodiment of the present invention.

FIG. 4 illustrates the classification of PCMO devices in accordance with embodiments of the present invention.

FIG. 5 is a graph showing hysteresis loops for two types of memory devices according to an embodiment of the present invention.

FIG. 6 illustrates the characteristics of the PCMO devices illustrated in FIG. 5.

FIGS. 7A-7D illustrate various steps in the fabrication of a memory device according to an embodiment of the present invention.

FIG. 8 illustrates a memory device structure according to another embodiment of the present invention.

FIG. 9 illustrates the operation of a switchable resistor that has a clockwise hysteresis of current versus voltage and a switchable resistor that has a counter clockwise hysteresis of current to voltage.

FIG. 10 is a diagram of a back to back switching resistor in accordance with an embodiment of the present invention.

FIG. 11 is a diagram of the operation a tri-state back-to-back switching resistor device according to an embodiment of the present invention.

FIG. 12 illustrates first method for addressing the tri-states of the back to back switching device of FIG. 11.

FIG. 13 is a diagram illustrating identifying the 00 state vs. 01, 10 states (nondestructive read) according to an embodiment of the present invention.

FIG. 14 is a diagram illustrating identifying a 10 state vs. 01 state (destructive read, need to reinstall the state after read) according to an embodiment of the present invention.

FIG. 15 illustrates addressing single cell of an array according to an embodiment of the present invention.

FIG. 16 illustrates creating asymmetry in the device to eliminate the need for resetting the device according to an embodiment of the present invention.

FIG. 17 is a diagram illustrating the energy levels in the metal oxide and the barrier layer's impact on the movement of oxygen ions according to an embodiment of the present invention.

### DETAILED DESCRIPTION

The present disclosure relates generally to memory devices, and more particularly to a memory device that includes a heterojunction oxide material and a barrier layer. The following description is provided to enable one of ordinary skill in the art to make and use the disclosed memory device. Various modifications to the preferred embodiments and the generic principles and features described herein will be readily apparent to those skilled in the art. Thus, the present disclosure is not intended to be limited to the embodiments shown, but is to be accorded the widest scope consistent with the principles and features described herein.

The present disclosure is directed to a memory device, methods of forming the device, and systems comprising the device. The memory device can be utilized in a variety of applications from a free standing nonvolatile memory to an embedded device in a variety of applications. These applications include but are not limited to embedded memory used in a wide range of SOC (system on chip) or system on package, switches in programmable or configurable ASIC, solid state drive used in computers and servers, memory used in mobile electronics like camera, cell phone, electronic pad, and build in memory in micro devices such as RF chips, mobile sensors and many others.

The memory device comprises a first metal layer and a first metal oxide layer coupled to the first metal layer. The memory device includes a barrier layer coupled to the first metal oxide layer. The memory device includes a second metal oxide layer coupled to the barrier layer and a second metal layer coupled to the second metal oxide layer. These metal layers, barrier layers, and metal oxide layers can be of a variety of types and their use will be within the spirit and scope of the present disclosure. More particularly, many of the embodiments disclosed herein will include PCMO as one of the metal oxide layers. It is well understood by one of ordinary skill in the art that the present disclosure should not be limited to this metal oxide layer or any other layer disclosed herein.

In some embodiments, the formation of the first metal oxide layer has a Gibbs free energy that is lower than the Gibbs free energy for the formation of the second metal oxide layer and there is a barrier layer of wider band gap material or higher oxygen diffusion constant than the first metal oxide, the second metal oxide, or both. The difference in the band gap will form a barrier to prevent oxygen ions or vacancies from moving between the first metal oxide and the second metal oxide. This barrier can serve to improve the retention of a resistance memory state even after the electric field is removed. The resistance memory state is typically formed by an externally applied electric field which drives the oxygen ions or vacancies from either the first metal oxide or the second metal oxide into the other metal oxide layer.

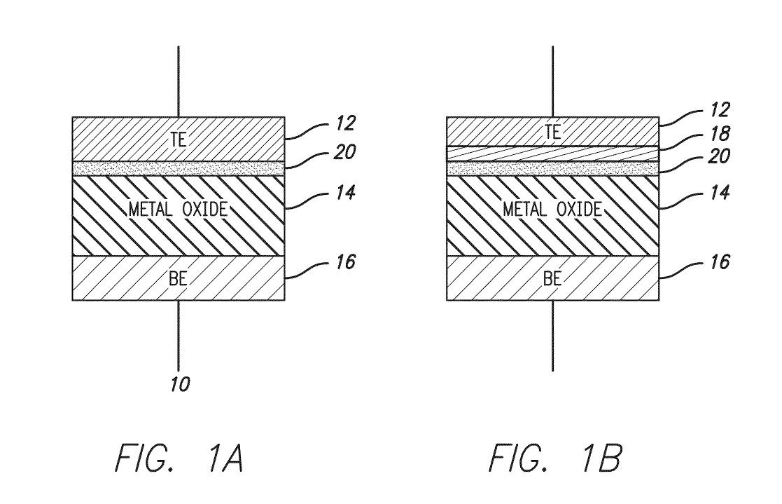

FIG. 1A is an illustration of a memory device 10 according to an embodiment of the present invention. Memory device 10 includes a bottom electrode 16. In some embodiments, bottom electrode 16 may be fabricated from Platinum (Pt), Aluminum (Al), Ruthenium (Ru), Copper (Cu), Gold (Au) or any other metal or conductive material. Bottom electrode has a top surface and a bottom surface. A metal oxide layer 14 is coupled to the top surface of bottom electrode 16. In some embodiments, metal oxide layer 14 can include one or more of Praseodymium Calcium Manganese Oxide (PCMO), Lanthanum Calcium Manganese Oxide (LCMO), Hafnium oxide (HfxOy), Aluminum oxide (AlxOy), Tantalum oxide (TaxOy) or any other metal oxide. In some embodiments, metal oxide layer 14 can be a multi-layered structured that includes more than one material, phases or configurations of metal oxide. For example, metal oxide layer 14 may be multi-layered comprising an amorphous layer of LCMO with a crystalline layer of LCMO. Other examples of multi-layered metal oxide layer 14 include a layer of PCMO with a layer of LCMO formed over the PCMO layer, or a layer of Aluminum oxide with a layer of Hafnium oxide formed over the Aluminum oxide layer and a layer of Tantalum oxide formed over the Hafnium oxide layer.

Metal oxide layer 14 is coupled to a barrier layer 20. Barrier layer 20 may include one or more wide band gap (or insulating) and oxygen ion or vacancy diffusion barrier materials such as Aluminum oxide (AlxOy), Hafnium oxide (HfxOy), Nickel oxide (NixOy), Tantalum oxide (TaxOy) or any other wide band gap material that has wider band gap than the metal oxide layer and can serve as oxygen ion or vacancy diffusion barrier. In some embodiments, barrier layer 20 may itself be a layered material of one or more materials, phases, or configurations exhibiting a characteristic of wide band gap compared to the metal oxide layer 14. In other embodiments, barrier layer 20 may or may not be a metal oxide. Barrier layer is coupled to a top electrode layer 12. Top electrode 12 may be formed from a metal including Platinum (Pt), Aluminum (Al), Ruthenium (Ru), Copper (Cu), Gold (Au), Tantalum (Ta), Titanium (Ti), Tungsten (W) or other.

FIG. 1B illustrates a particular structure for a memory device according to an embodiment of the present invention. As illustrated in FIG. 1B, a top metal oxide layer 18 is coupled to barrier layer 20. This top metal oxide layer 18 may form at the interface of barrier layer 20 and top electrode 12 when (i) a Gibbs free energy of oxidation of top electrode 12 is less (more negative) than a Gibbs free energy for the formation (oxidation) of the metal oxide layer 14 or (ii) the Gibbs free energy of oxidation of top electrode 12 is less (more negative) than a Gibbs free energy of oxidation of the barrier layer 20. Top metal oxide 18 may be spontaneously formed or may form as a result of externally applied potential to the memory device. In some embodiments, top metal oxide layer 18 may form as a result of heating. In other embodiments, top metal oxide 18 may be deposited rather than formed at the interface of barrier layer 20 and top electrode 12. The deposited top metal oxide layer may have a Gibbs free energy of oxidation more or less than a Gibbs free energy of oxidation for metal oxide layer 14. Also, the deposited top metal oxide layer may have a Gibbs free energy of oxidation more or less than a Gibbs free energy of oxidation for barrier layer 20.

In some embodiments, metal oxide layer 14 is thicker than top metal oxide layer 18. In an embodiment, metal oxide layer 14 is 10 to 100 times thicker than top metal oxide layer 18. For example, the thickness of top metal oxide layer 18 may be in the range of 10 to 100 angstroms and the thickness of metal oxide layer 14 may be between 100 to 10000 angstroms.

Barrier layer 20 is preferably thin and may be between 5 to 50 angstroms to allow for direct diffusion, passing, or tunneling of oxygen ions or vacancies from metal oxide layer 14 to top electrode metal 12. This direct diffusion/passing/tunneling of oxygen ions or vacancies may be spontaneous or may occur in response to an externally applied electrical or chemical potential. In a particular embodiment, barrier layer 20 is between 20 and 30 angstroms thick. Barrier layer 20 serves to slow down or stop the diffusion of oxygen ions or vacancies between metal oxide layer 14 and top electrode metal 12, especially when externally applied potential is removed. Thus, barrier layer 20 may improve data retention of the memory device.

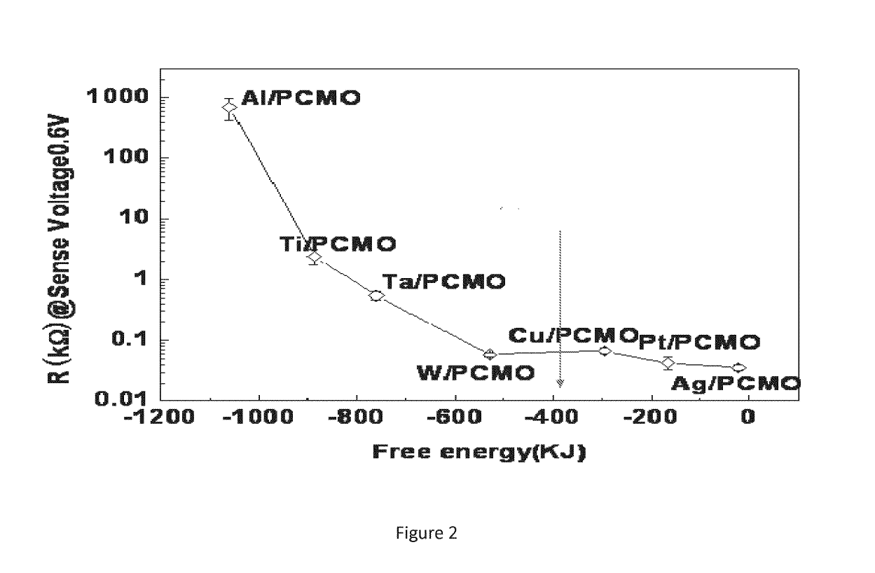

FIG. 2 is a graph that shows resistance versus the Gibbs free energy values of oxidation for various metals that may be used in forming top electrode 12 illustrated in FIGS. 1A and 1B. The vertically downward arrow designates the Gibbs free energy for PCMO. As illustrated in FIG. 2, the Gibbs free energy for oxidation of PCMO is about −400 KJ. As can be seen from FIG. 2, elements such as gold, silver, and platinum, which have a higher (i.e. less negative) oxidation Gibbs free energy than PCMO, will not spontaneously form oxide at the contact with the PCMO. However aluminum, titanium, and tantalum, which have a lower (i.e. more negative) oxidation Gibbs free energy than PCMO may form the top metal oxide layer over barrier layer 20. The formation of PCMO may be spontaneous or with applied external potential such as electrical bias or heat.

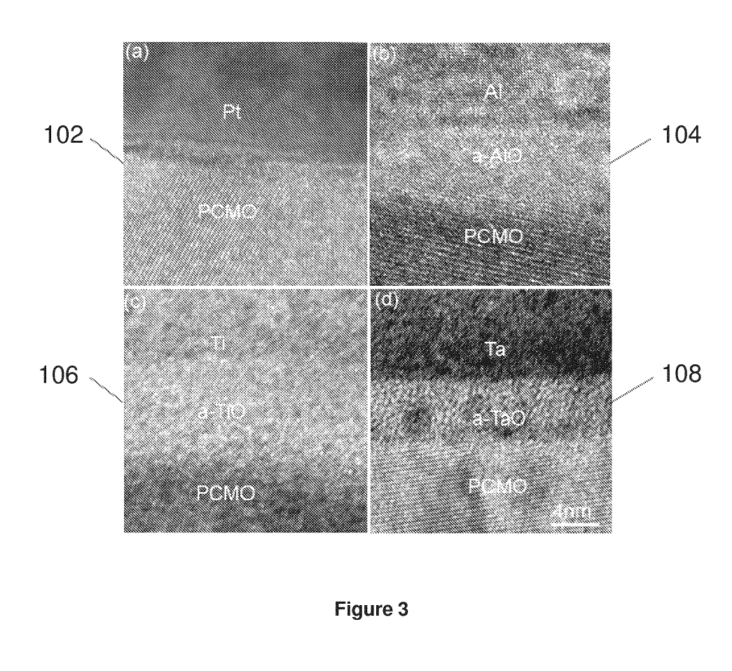

FIG. 3 is a set of cross sectional transmission electron micrographs (TEM) that illustrate formation of (or lack thereof) a metal oxide layer at the interface of a PCMO layer and a metal electrode layer. In TEM 102, an interface between Platinum and PCMO has no noticeable layer of metal oxide as predicted by the Gibbs free energy of oxidation graph of FIG. 2. TEM's 104, 106, and 108 each illustrates the formation of a metal oxide at the interface between the PCMO layer and the top electrode layer when aluminum, titanium and tantalum respectively are used as the top electrode material. This is also in-line with the graph of FIG. 2 above.

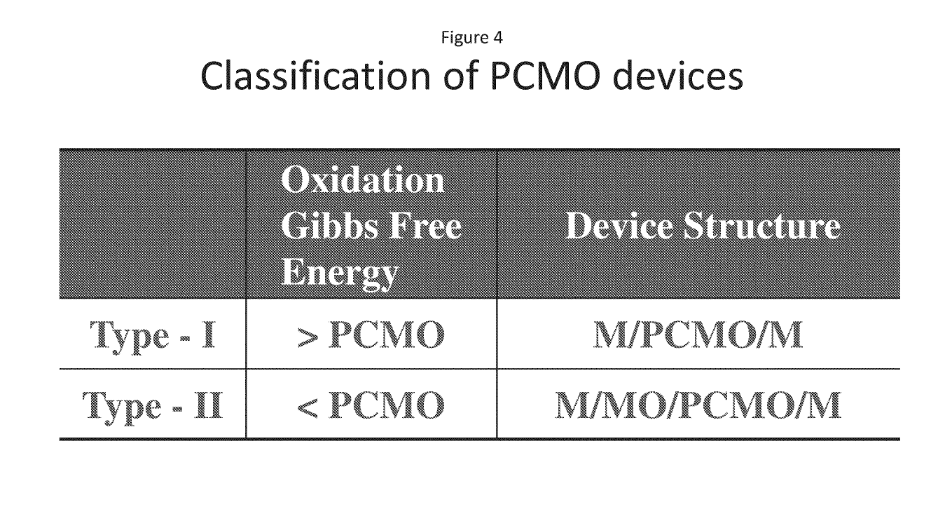

FIG. 4 is a table showing various classifications of a memory device according to an embodiment of the present invention. A memory device can be classified in one of two types based on the relative value of the oxidation Gibbs free energy of the metal compared to the oxidation Gibbs free energy of PCMO. In this embodiment, metal oxide layer 14 of FIG. 1A (or 1B) is implemented using a PCMO layer. For a Type I device, top electrode 12, barrier layer 20, and bottom metal electrode 16 each has a higher oxidation Gibbs free energy than the oxidation Gibbs free energy of PCMO. The final device structure for this instances is metal-(barrier layer)-PCMO-metal or M/PCMO/M as shown in FIG. 1A.

For a Type II device, top electrode 12 has a lower oxidation Gibbs free energy than the oxidation Gibbs free energy of PCMO (implemented as metal oxide layer 14) or the barrier layer 20. In this instance, top metal oxide 18 may form at the interface of the PCMO layer and barrier layer 20 resulting in a device structure that has a metal-top metal oxide-(barrier layer)-PCMO-metal configuration or M/MO/PCMO/M as shown in FIG. 1B. Thus, it can be said that a Type II device is a heterojunction metal oxide device.

The above description of using the relative values of the oxidation Gibbs free energy with respect to metal oxide 14 of the device configuration of FIGS. 1A and 1B can be generalized to any metal that may be used for forming top electrode 12. For example, Al, Ta, and Ti when used for forming top electrode 12 can form Type II device with Tungsten Oxide as metal oxide 14 that may be coupled to Platinum, Gold, or Silver as bottom electrode 16 as indicated in by the Gibbs free energy graph of FIG. 2. In addition, top metal oxide 18 may be either deposited or grown. The growth of top metal oxide 18 may be due to a spontaneous formation attributed to Gibbs free energy of oxidation difference or due to an applied potential, as described above.

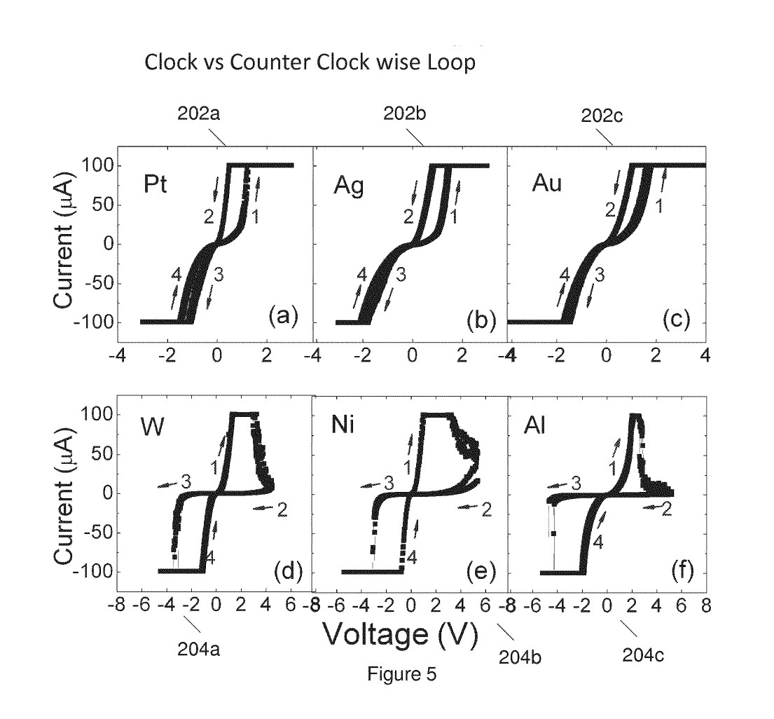

FIG. 5 shows several current-voltage (I-V) hysteresis curves for Type I and Type II devices. As illustrated in curves 202a, 202b, and 202c, a Type I device may yield a counter clock wise (CCW) hysteresis loop. However, as illustrated in curves 204a, 204b, and 204c, a Type II device may yield a clock wise hysteresis loop. Furthermore, the hysteresis loop of the Type II device may be considerably larger than the hysteresis loop of Type I devices. The CCW loop and CW loop may be swapped if the polarity of the bias is interchanged. These unique I-V characteristics can be utilized for various applications. Devices using such I-V characteristics include but are not limited to memory devices, current switches, diodes, etc.

The different hysteresis loops shown in FIG. 5 illustrate that for Type II devices, base metal oxide 14 (e.g., PCMO) and top metal oxide 18 may each function as a switchable resistor. Thus, a voltage with the correct polarity and amplitude can cause either resistor to switch from a low resistive state (LRS) to a high resistive state (HRS) or from a HRS to a LRS.

In a particular embodiment, the switch from LRS to HRS is used to ‘reset’ the memory device and the transition from HRS to LRS is used to ‘set’ the memory device. In some embodiments, the lower oxidation Gibbs free energy of the top electrode in a Type II device may result in a more stable top oxide layer structure which has a higher resistance in HRS than the resistance of PCMO in HRS. For example, the top metal oxide layer maybe significantly thinner than PCMO and the resistance of the top metal oxide layer at LRS may be comparable to or lower than the resistance of PCMO at HRS. This feature maybe utilized in the following way.

When a Type II device containing a top metal oxide layer is in the HRS; most of the voltage applied to the Type II device will drop across the top metal oxide and hence create a high internal field that causes the switching from the HRS to the LRS (‘set’). Many mechanisms for this switching are possible. For example, the internal field may push oxygen ions or vacancies through and out of the top metal oxide layer into the PCMO layer (i.e. base or bottom metal oxide layer), thus reducing the top metal oxide layer thickness. This movement of the oxygen ion or vacancy may be optionally through barrier layer 20.

On the other hand, when the Type II device is in the LRS, the voltage applied to the Type II device will be shared in the top metal oxide layer and in the PCMO layer or can be more in the PCMO layer. This allows field induced oxygen ion or vacancy migrations through and out of the PCMO layer into the top metal oxide layer and the top metal electrode layer. The influx of oxygen ions into the top metal oxide layer may cause further oxidation of the top metal electrode layer at the interface with the top metal oxide layer and may thus increase the thickness of the top metal oxide layer and cause the resistance of the device to switch from the LRS to the HRS (reset). Again, this movement of the oxygen ion or vacancy out of the PCMO layer may optionally pass through barrier layer 20.

The relative layer thickness of the top metal oxide and the PCMO layers may be adjusted to secure desired levels of switching speed, switching potential, or both. These thickness adjustments may be produced by deposition condition changes and/or by depositing an initial top metal oxide layer before the deposition or the formation of top metal oxide layer 18.

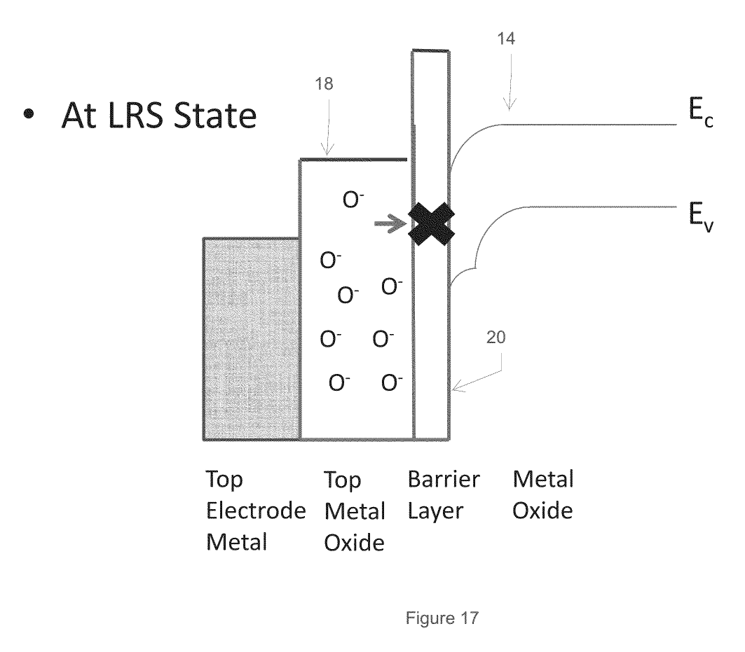

In some embodiments, a barrier layer may be introduced between the PCMO layer and the top metal oxide layer. FIG. 17 illustrates a memory device structure according to another embodiment of the present invention. As illustrated in FIG. 17, a barrier layer 20 is present between PCMO layer 14 and top metal oxide layer 18. Barrier layer 20 can improve the stability of a Type II device. During the RESET operation, the applied external potential may cause oxygen ions or vacancies to migrate through and out of PCMO layer 14 into top metal oxide layer 18, which may result in an increase in the thickness of top metal oxide layer 18 and causes a switch from the LRS to the HRS. The resulting HRS state concentrates oxygen ions, whether bonded to top metal oxide layer 18 or freely moving, in top metal oxide layer 18. This concentration of oxygen ions sets up a built-in field which can result in a drift current of oxygen ions out of top metal oxide layer 18. Diffusion forces also tend to move oxygen ions from high concentration regions such as top metal oxide layer 18 to low concentration regions such as PCMO layer 14. These drift and diffusion forces are generally weaker than the applied external potential but when the applied external potential is removed, the drift and diffusion forces can result in deterioration of the HRS by reducing the effective thickness of top metal oxide layer 18.

Although FIG. 17 shows barrier layer 20 functioning to reduce oxygen ion movement in one resistance state, it is to be noted that barrier layer 20 can also reduce oxygen ion or vacancy movement in other resistance states. For example, in the LRS, it may be possible for drift and diffusion forces to result in a net migration of oxygen ions from PCMO layer 14 to top metal oxide layer 18 after the applied ‘SET’ external potential is removed. This migration can also result in the deterioration of the LRS state by increasing the effective thickness of top metal oxide layer 18. For some devices, the oxygen ion movement may be better described as oxygen vacancy movement, and it is to be noted that barrier layer 20 can also be said to reduce oxygen vacancy movement for the devices.

The deterioration of the separate resistance states HRS and LRS, such as by diffusion of oxygen ions, can result in difficulty in distinguishing the two states. When the Type II devices are used, for example, as memory devices, such deterioration erodes the ability to distinguish between the two resistance states and consequently deteriorates data retention capability of the memory device. Therefore a solution to this problem would be advantageous, e.g., in the utility of the Type II devices of the present disclosure as memory devices.

Barrier layer 20 described above can serve as a solution to the aforementioned problem of data retention. A barrier layer of wide band gap or an oxygen ion diffusion barrier material may serve to impede the drift and diffusion of the oxygen ions into or out of the top metal oxide layer thus improving the stability of the individual RHS and LHS states. This improvement can thus result in improvement in data retention of digital data written into arrays of the Type II devices of the present disclosure as distinct RHS and LHS states.

The barrier layer can further serve as a means for adjusting Type II devices in order to secure desired levels of switching speed, switching potential, or both. This adjustment may be useful in, for example, preventing early switching from occurring during voltage ramp up. For example, for the oxygen ions to diffuse through the barrier layer, a minimum voltage may be needed, thus preventing early switching of resistance states during switching. This may improve resistance switching uniformity. Barrier layer 20 may thus improve the uniformity of an array of many devices to achieve a narrow switching distribution. Such narrower switching distribution may result in better overall performance of the memory system. In some embodiments, it would be easier to distinguish between the LRS and the HRS bits in the array, thus requiring less overhead such as error correction and allow for faster response time.

Further such improved control as provided by the narrower switching distribution can be used to allow for multiple digital data bits to be stored in a single device by allowing for multiple resistance stages to be distinguished in every cell in an array. For example, if the LRS allows for 1 microamps (μA) of current to pass through the device at 1 Volt (V) of bias, and the HRS allows for 0.1 μA of current to pass through the device at 1 V of bias, then the window would be 1-0.1=0.9 μA. Then, if groups of devices, e.g., a sector of 1000 memory devices, were to be “read” and compared to a reference cell which allows 1 μA of current at 1 V of bias to determine the cells at LRS, the distribution of the currents for the 1000 memory devices influences whether it is easy to determine whether each device is in the LRS or the HRS. If the LRS currents are centered around 1 μA with an distribution of +/−0.5 μA (i.e. 0.5 μA to 1.5 μA) and the HRS currents are centered around 0.1 μA with a distribution of +/−0.5 μA (i.e., −0.4 μA to 0.6 μA), then the two distributions would overlap and there will be some devices for which it would be difficult to discern whether they are in the LRS or the HRS.

However, if the LRS currents are centered around 1 μA with a distribution of +/−0.1 μA (i.e. 0.9 μA to 1.1 μA) and the HRS currents are centered around 0.1 μA with a distribution of +/−0.1 μA (i.e. 0 μA to 0.3 μA), then the two distributions would be easily distinguishable and no devices would be in an ambiguous state. Further, additional states between the LRS and the HRS may be distinguishable. For example a middle resistance state (MRS) may be centered on 0.5 μA with a +/−0.1 μA distribution (i.e. 0.4 μA to 0.6 μA), and still be distinguishable from LRS and HRS devices as the distributions do not overlap. If 4 distinguishable states can be supported, then two bits of memory can be stored in a single device.

Am embodiment of the present invention that includes a barrier layer provides a heterojunction memory device which can potentially retain data over a long period of time (e.g., 10+ years). The heterojunction memory device may be implemented in a variety of memory functions such as dynamic random access memory (DRAM), static random access memory (SRAM), one-time programmed memory (OTP), nonvolatile memory (NVM), embedded memory, cache memory, and others.

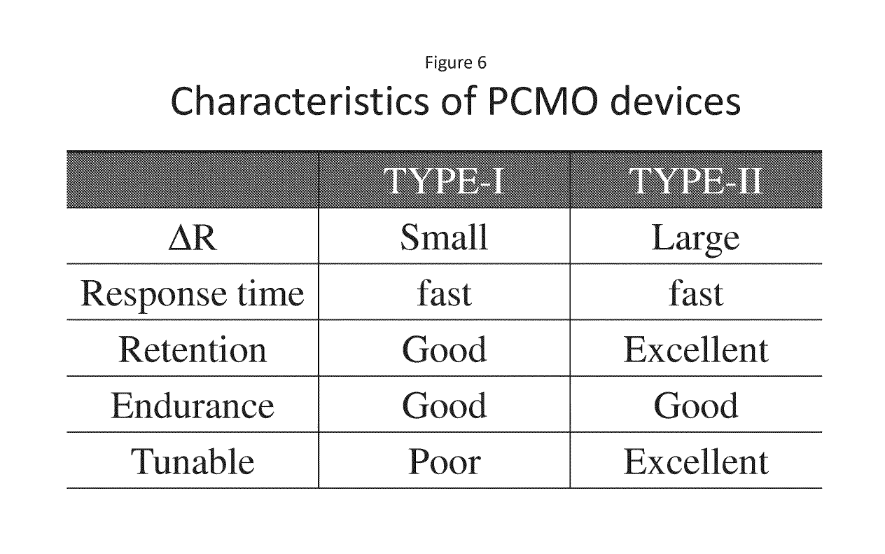

FIG. 6 illustrates the characteristics of Type I and Type II devices. As can be seen in FIG. 6, although both types of devices can be utilized as memory devices, the Type II device may be more effective and may have better characteristics. As described above, in a Type II device, the formation of the first metal oxide layer has a Gibbs free energy that is lower than the Gibbs free energy for the formation of the second metal oxide layer or the barrier layer. As a result, the two metal oxide layers provide a heterojunction that allows for the continual setting and resetting of the device.

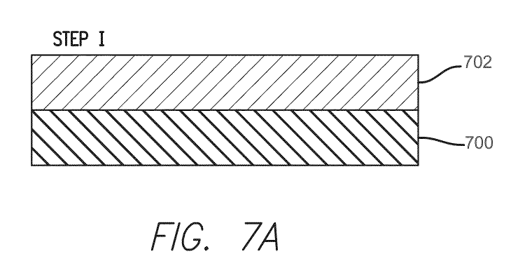

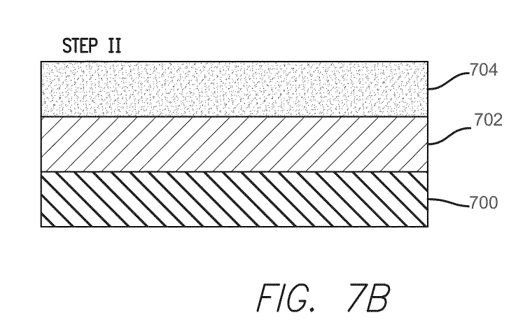

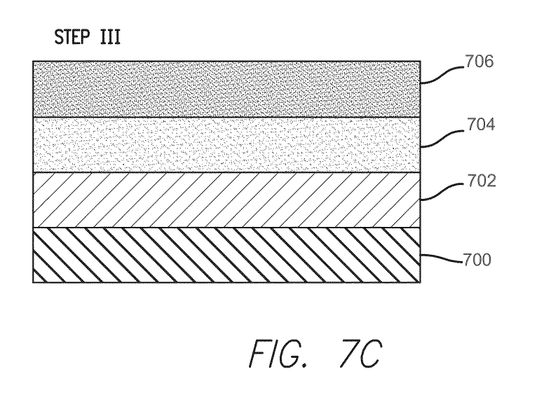

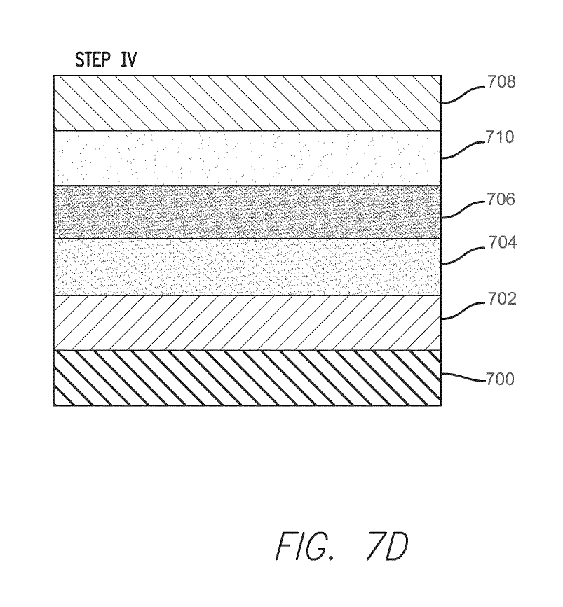

FIG. 7A-7D illustrate steps in a process of fabricating a Type II heterojunction device according to an embodiment of the present invention. The Type II device so manufactured is capable of functioning as a memory device. As illustrated in FIG. 7A, a substrate 700 is provided. In some embodiments, substrate 700 may be a silicon substrate. It is to be noted that other types of substrates may also be used. A metal layer 702 is formed over an upper surface of substrate 700. In some embodiments, metal layer 702 may include one of Platinum (Pt), Aluminum (Al), Ruthenium (Ru), Copper (Cu), Gold (Au) or any other metal or conductive substrate. Metal layer 702 may be deposited using commonly known semiconductor fabrication techniques such as chemical vapor deposition (CVD) or physical vapor deposition (PVD), Sputtering, or the like. In some embodiments, metal layer 702 may be between 50 angstroms (Å) and 2000 Å in thickness. Thereafter a first metal oxide layer 704 may be deposited over the metal layer 702, as illustrated in FIG. 7B. In some embodiments, first metal oxide layer can include PCMO, LCMO, Tungsten Oxide, or Titanium Oxide and can be between 100 Å and 10000 Å in thickness. First metal oxide layer 704 can be deposited using any of the known semiconductor fabrication techniques described above.

Thereafter, a barrier layer 706 is formed over first metal oxide layer 704 as illustrated in FIG. 7C. Barrier layer 706 may be formed using a bandgap material and may be between 5 and 50 angstroms in thickness. In a particular embodiment, barrier layer 706 is between 10 and 30 angstroms thick. In one embodiment, an atomic layer deposition (ALD) process may be used to deposit barrier layer 706. In order to be an effective barrier, the non-uniformity of the barrier layer is preferred to be less than 5%. In a particular embodiment, the non-uniformity of barrier layer 706 is between 1% and 5%. ‘Non-uniformity’ of a layer is well-known concept in semiconductor fabrication industry and the discussion of that is omitted here for sake of brevity. FIG. 7D illustrates the next step in forming the memory device. A second metal layer 708 is formed over barrier layer 706. Second metal layer 708 can be formed using one of physical vapor deposition techniques such as sputtering and evaporation, chemical vapor deposition techniques, and atomic layer deposition techniques and others. In some embodiments, the thickness of second metal layer 708 is between 30 Å and 10000 Å. As described above, if the Gibbs free oxidation energy of second metal layer 708 is lower than the Gibbs free energy of metal oxide layer 704, a second metal oxide layer 710 is spontaneously formed at the interface of second metal layer 708 and barrier layer 706. In some embodiments, the thickness of the second metal oxide layer can range between 100 Å and 1000 Å. The device structure illustrated in FIG. 7D can then be processed using known semiconductor fabrication techniques to create a functioning memory device.

It should be appreciated that the specific steps illustrated in FIGS. 7A-7D provide a particular method of fabricating a memory device according to an embodiment of the present invention. Other sequences of steps may also be performed according to alternative embodiments. For example, alternative embodiments of the present invention may perform the steps outlined above in a different order. Moreover, the individual steps illustrated in FIGS. 7A-7D may include multiple sub steps that may be performed in various sequences as appropriate to the individual step. Furthermore, additional steps may be added or removed depending on the particular applications. One of ordinary skill in the art would recognize many variations, modifications, and alternatives.

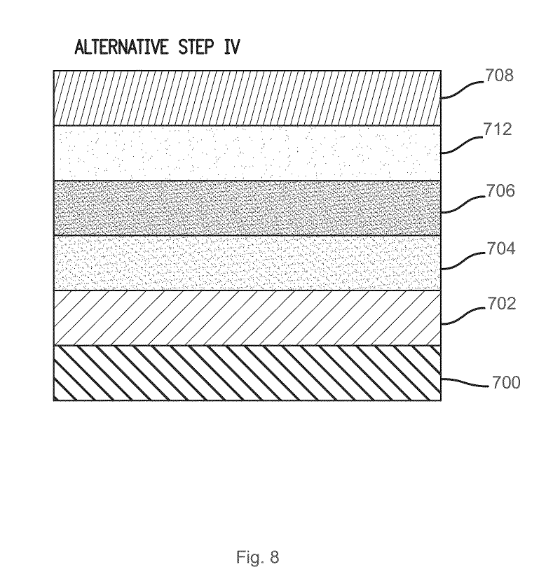

For example, FIG. 8 illustrates an alternative method for forming the memory device according to another embodiment of the present invention. As illustrated in FIG. 8, second metal oxide layer 710 is deposited over barrier layer 708 instead of it spontaneously forming as in FIG. 7D above. Thereafter, an inert metal layer 712 is provided on top of second metal oxide layer 710. In this instance, inert metal layer 712 forms a top electrode. Examples of inert metals that can be used for inert metal layer 712 include but are not limited to Platinum, Gold, and Silver. Through the use of the processes described above, a heterojunction oxide device with barrier layer can be provided that has memory characteristics that are significantly better than current art memory devices.

The heterojunction device with barrier layer described herein can function as a switchable resistor that can be used to construct high density memory arrays. Since the heterojunction device is a bipolar device, in general, it may require additional circuitry for its operation (e.g., to select, set, reset and read individual devices in the array).

In some embodiments, back-to-back heterojunction resistive devices may be utilized in a system to eliminate the need of the transistor circuit. This type of memory system may use less power and may need fewer processing steps than conventional memory systems. More importantly it may allow an easy way for forming a multi stack memory cell that further improves the cell density per unit source area, which a measure of the efficiency/effectiveness of a memory device.

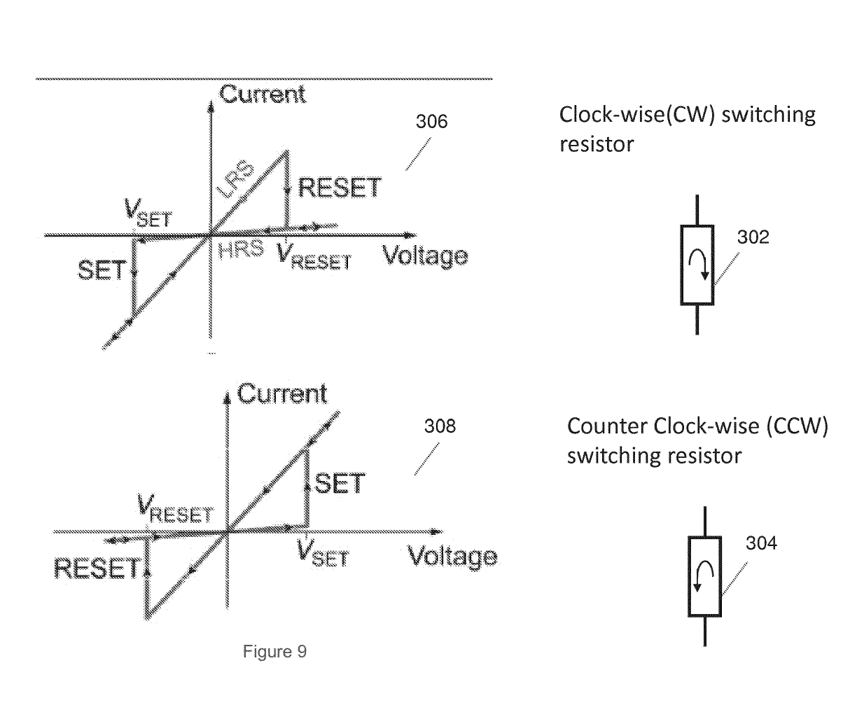

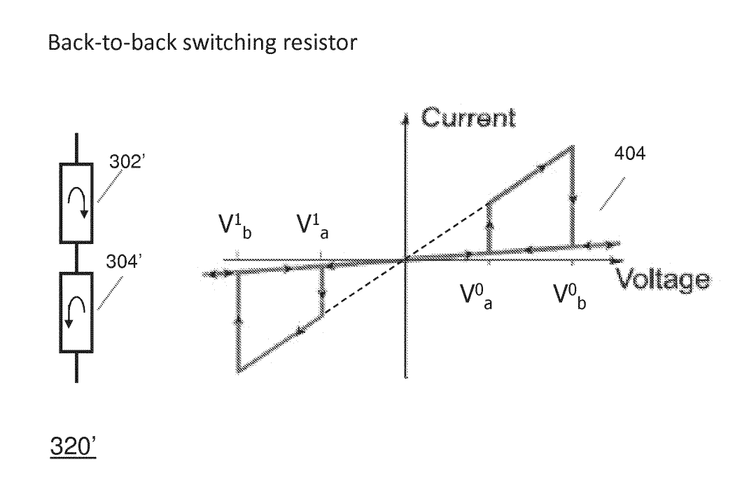

FIG. 9 illustrates a switchable resistor 302 that has an idealized clockwise hysteresis of current versus voltage (I-V) 306. Another switchable resistor 304 has an idealized counter clockwise I-V hysteresis 308. Switching resistors 302 and 304 can be either a Type II or a Type I device by the choice of the top metal electrode. In some embodiments, switching resistors 302 and 304 can both be a Type I or a Type II device with top and bottom electrode reversed in them. FIG. 9 illustrates idealized I-V characteristics for the switching resistor devices for ease of explanation.

For example, for the clockwise switching resistor 302, the I-V curve 306 shows that as the voltage is swept in the positive voltage direction, the current flow through the resistor switches from the higher current LRS to the lower current HRS forming a clockwise loop in the positive voltage I-V. As the bias voltage is swept in the negative voltage direction, the current flow through the resistor switches from the lower current HRS to the higher current LRS, again, forming a counter-clockwise I-V loop in the negative voltage direction.

Similarly, for the counter-clockwise switching resistor 304, the I-V curve 308 shows that as the voltage is swept in the positive voltage direction, the current flow through the resistor switches from the lower current HRS to the higher current LRS forming a counter-clockwise loop in the positive voltage IV. As the bias voltage is swept in the negative voltage direction, the current flow through the resistor switches from the higher current LRS to the lower current HRS, again, forming a clockwise I-V loop in the negative voltage direction. It should be clear to one of ordinary skill in the art that a real device will have an I-V curve that differs from the idealized curves illustrated in FIG. 9. However, the principle remains valid even with a non-idealized (i.e., real world) I-V curves for a device.

FIG. 10 is a diagram of a back to back switching device 320 in accordance with an embodiment of the present invention. The I-V characteristics of such a combined device are illustrated by hysteresis diagram 404. These two resistors 302 and 304 may have identical idealized I-V characteristics but with opposite polarities. The I-V characteristics are opposite due to the fact that when one resistor is switching from HRS to LRS, the other resistor is switching from LRS to HRS. By using a switching voltage that is between the threshold voltages Va and Vb (within positive side or negative side), both resistors 302 and 304 can be switched from HRS to LRS.

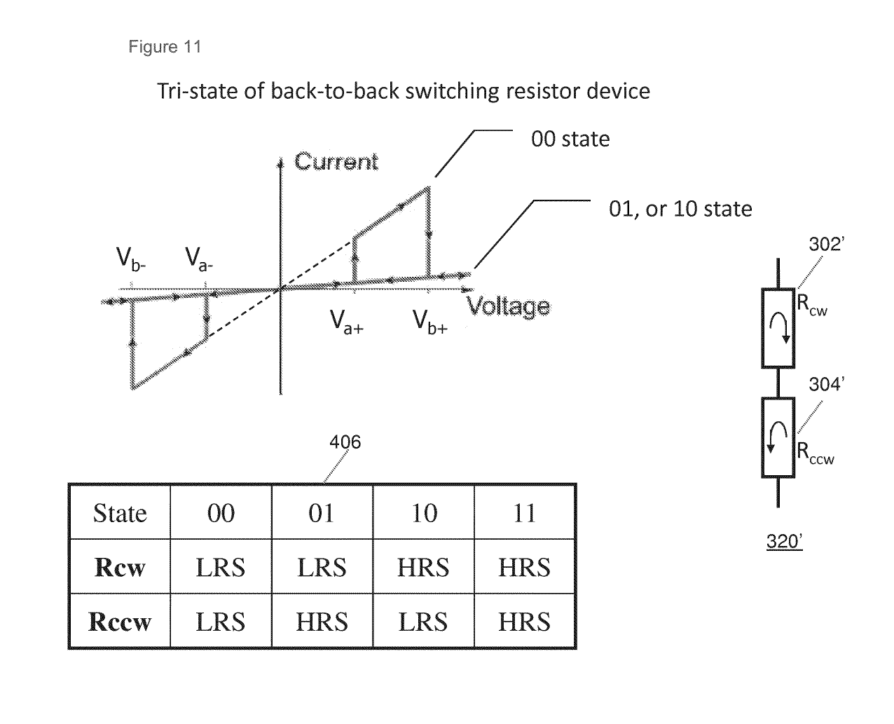

FIG. 11 shows that back-to-back switching device 320 can give rise to a tri-state. When either resistor 302 or 304 is in HRS, the combined device 320 is in HRS. So there are two HRS for device 320. They can be represented as the 01 or the 10 state. When both resistors are in LRS, the device is in LRS, or the 00 state. When both switching resistors 302 and 304 are in HRS, device 320 is in HRS. This can be represented by the 11 state. All these states are illustrated in table 406.

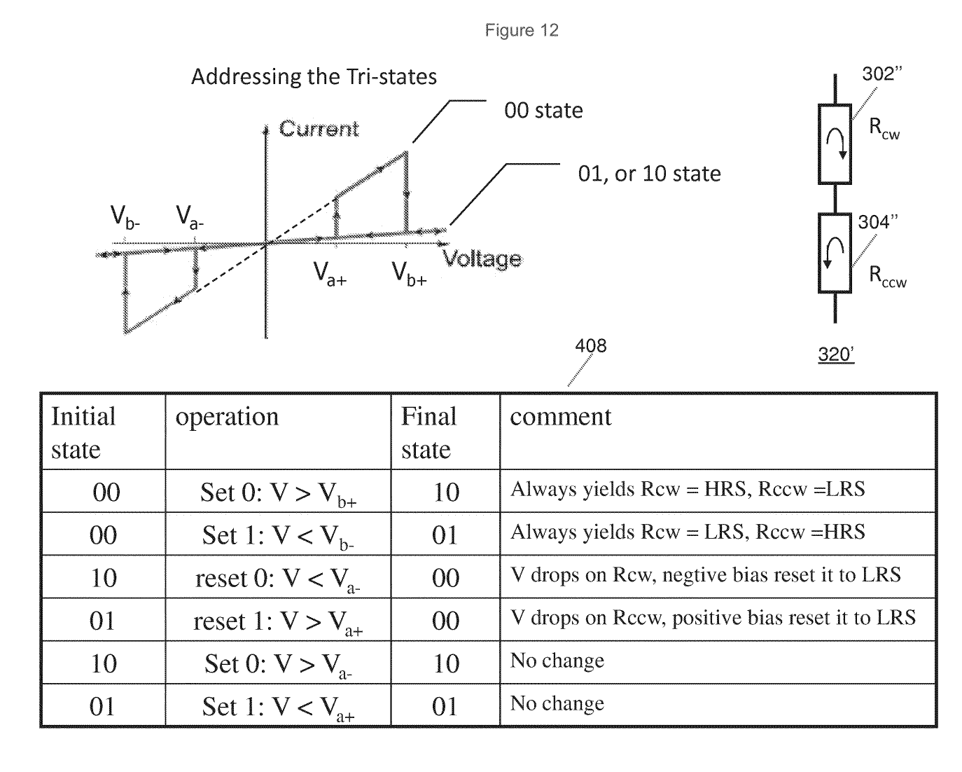

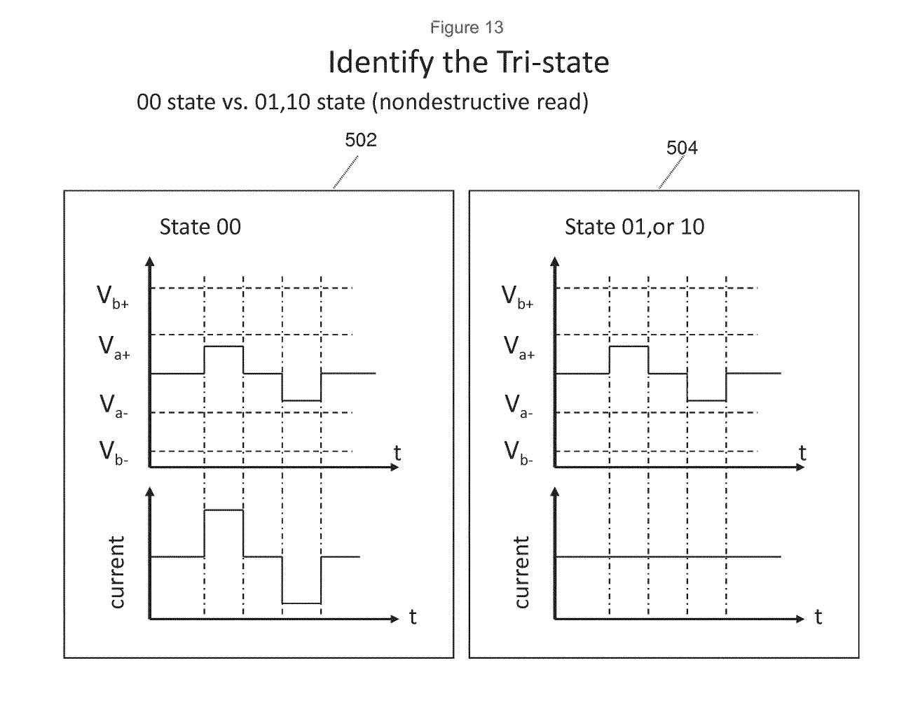

FIG. 12 illustrates a table 408 that includes information for addressing the tri-states of the back-to-back switching device 320 of FIG. 11. In general, the 00 state can be set to the 01 or the 10 state and vice versa. FIG. 13 is a diagram illustrating a method to identify the 00 state illustrated in graph 502 vs. 01, 10 states illustrated in graph 504. In this instance the read voltage for the memory device is within the two lower threshold voltages (Va−<V<Va+), therefore the device will remain in the original state. This is referred to herein as a nondestructive read, where the process of reading, or identifying the state of the device does not change the state of the device.

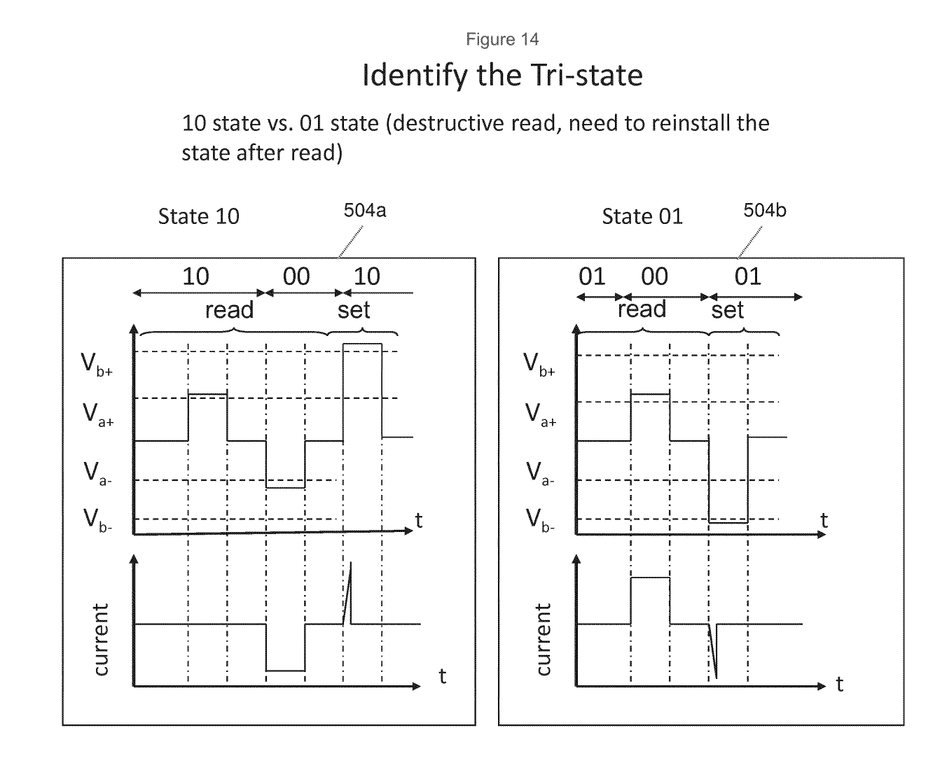

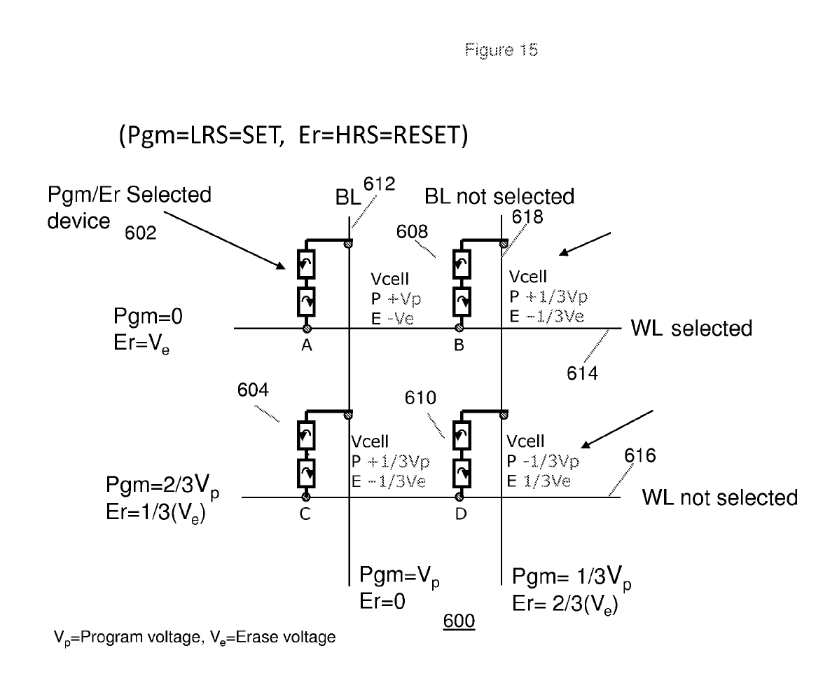

The nondestructive read described above can only differentiate the 00 state (LRS) from either the 01 or 10 state (HRS state). To further differentiate between the 01 and 10 state, the polarity of the switching voltage (Vb'<V<Va− or Va+<V<Vb+) that causes the switching of the resistor from HRS to LRS needs to be tested. This is a destructive read (i.e. where the process of identifying the state of the device alters the state of the device and destroys the data stored in the device. Therefore an additional program or erase pulse is needed to reset the device to the initial state before the destructive read to restore the previously stored state into the device. FIG. 14 is a diagram illustrating a method for identifying a 10 state vs. a 01 state. It is readily apparent to one of ordinary skill in the art that many other voltage pulses and sequences can be generated to read the tri-state.

The addressable and readable tri-state of a back-to-back switching resistor device can be used to create a memory array that avoids the need of an active transistor circuit to perform the select and set/reset and read. For example, since the 01 and 10 states are two addressable and distinguishable HRS, they can be assigned to be the 0 or 1 state of a memory cell. Since both 0 and 1 state have high resistance, the system should have very low leakage current. A positive voltage greater than Vb+ or a negative voltage smaller than Vb− can set the device to 1 or reset the device to 0 as shown in table 408 of FIG. 12. For a destructive read operation, a test pulse can be applied to the device to set the cell to 00 state and from the polarity of the bias to extract the 10 or 01 state. Note that the original state needs to be reinstalled after any destructive read operation.

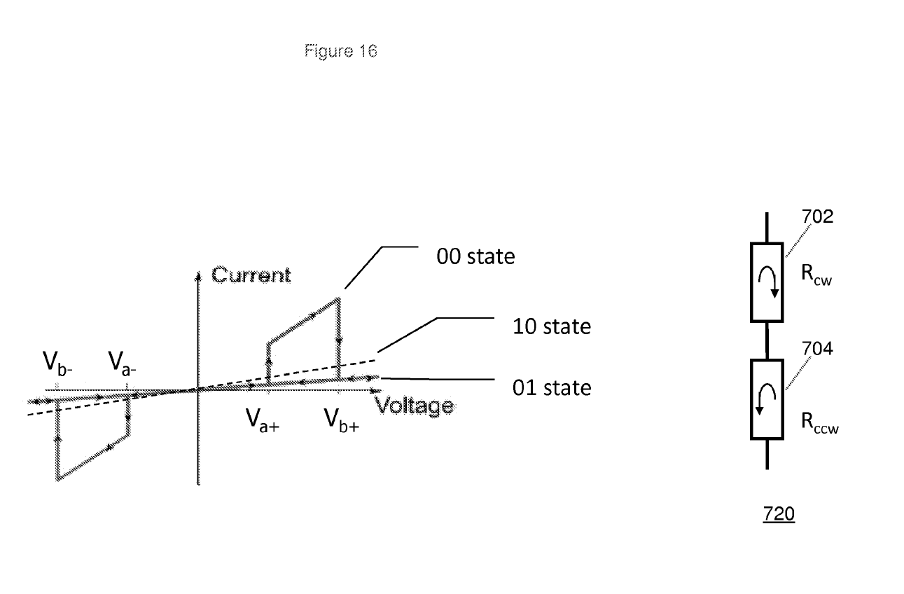

Memory devices are typically built and operated as arrays where many devices share bit lines and word lines to conserve space, cost, and speed of operation. Thus, in order to operate a particular memory cell in a memory cell array, e.g., for read, program or erase, determination of proper voltage on the bit line and word line may be needed such that the states of the unselected cells in the memory array are not affected or disturbed during the operation of any particular, selected cell. The reduction of these read and write disturbs, where the states of the unselected cells in the memory array are affected during the operation of one or more selected cells is important to prevent data degradation and data error. FIG. 15 illustrates a diagram of biasing patterns according to an embodiment of the present invention. As illustrated in FIG. 15, the unselected bit lines and word lines are biased at a fraction of the program or erase voltages to allow for the unselected cells in the bit line or word line to experience only a fraction of the bias voltage thus reducing the disturbance to these unselected cells.

The above description is based on two identical heterojunction oxide resistors. If the HRS states of the two switching resistors 302 and 304 have sizable differences as illustrated in FIG. 16, then it is possible to perform a nondestructive read of a back-to-back resistor device. By so doing, we can eliminate the need for resetting the device after the read because the 10 and 01 HRS states would have a distinguishable current difference, i.e. one device would have the smaller resistor in the HRS, and the other device would have the larger resistor in the HRS.

Although the present disclosure has been described in accordance with the embodiments shown, one of ordinary skill in the art will readily recognize that there could be variations to the embodiments and those variations would be within the spirit and scope of the present disclosure. Accordingly, many modifications may be made by one of ordinary skill in the art without departing from the spirit and scope of the appended claims.

What is claimed is:

1. A memory device comprising:
a first metal layer;
a first metal oxide layer coupled to the first metal layer;
a barrier layer coupled to the first metal oxide layer;
a second metal oxide layer coupled to the barrier layer;
a second metal layer coupled to the second metal oxide layer;
wherein a Gibbs free energy for the formation of the first metal oxide layer is lower than the Gibbs free energy for the formation of the second metal oxide layer.

2. The memory device of claim 1 wherein the first metal layer comprises one of: Aluminum, Titanium, Tantalum, Gold, Silver, or Platinum.

3. The memory device of claim 1 wherein the first metal oxide layer comprises one of Praseodymium Calcium Manganese Oxide (PCMO), Lanthanum Calcium Manganese Oxide (LCMO), Hafnium oxide (HfxOy), Aluminum oxide (AlxOy), or Tantalum oxide (TaxOy).

4. The memory device of claim 1 wherein a thickness of the first metal oxide layer is in the range of 50 angstroms to 2000 angstroms.

5. The memory device of claim 1 wherein the first metal oxide layer has a first thickness that is three to five times greater than a second thickness of the second metal oxide layer.

6. The memory device of claim 1 wherein a thickness of the barrier layer is between 5 and 50 angstroms.

7. The memory device of claim 1 wherein the second metal layer comprises an inert metal.

8. A memory device comprising:
a substrate having a top surface and an opposing bottom surface;
a first metal layer coupled to the top surface of the substrate;
a Praseodymium Calcium Manganese Oxide (PCMO) layer coupled to the first metal layer;
a barrier layer coupled to the PCMO layer;
a metal oxide layer coupled to the barrier layer;
a second metal layer coupled to the metal oxide layer;
wherein a first Gibbs free energy for the metal oxide layer is lower than a second Gibbs free energy for the PCMO layer.

9. The memory device of claim 8 wherein the PCMO layer is characterized by a first thickness that is twenty to fifty times greater than a second thickness of the metal oxide layer.

10. The memory device of claim 8 wherein the second thickness is in the range of 10 to 50 angstroms.

11. The memory device of claim 8 wherein the barrier layer is between 10 and 30 angstroms thick.

12. The memory device of claim 8 wherein the first metal layer and the second metal layer comprises one of: Aluminum, Titanium, Tantalum, Gold, Silver, or Platinum.

13. The memory device of claim 8 wherein the metal oxide layer comprises one of TiO₂, Ta₂O₅, NiO, WO₃, or Al₂O₃.

14. The memory device of claim 8 wherein the PCMO layer is characterized by a first state having a first resistance and a second state having a second resistance and the metal oxide layer is characterized by a third state having a third resistance state and a fourth state having a fourth resistance, and wherein the first resistance is higher than the second resistance and the third resistance is higher than the fourth resistance.

15. A method of manufacturing a memory device, the method comprising:
providing a substrate having an upper surface and an opposing lower surface;
forming a first metal layer over the upper surface of the substrate;
forming a first metal oxide layer over the first metal layer, the first metal oxide layer having a thickness of between 500 and 1000 angstroms;
forming a barrier layer over the first metal oxide layer;
forming a second metal oxide layer over the barrier layer; and
forming a second metal layer over the second metal oxide layer,
wherein a first Gibbs free energy for the second metal oxide layer is lower than a second Gibbs free energy for the first metal oxide layer.

16. The method of claim 15 wherein the barrier layer comprises a wide bandgap material including one of Aluminum oxide (AlxOy), Hafnium oxide (HfxOy), Nickel oxide (NixOy), or Tantalum oxide (TaxOy).

17. The method of claim 15 wherein the second metal oxide layer is spontaneously formed at an interface of the barrier layer and the second metal layer.

18. The method of claim 15 wherein a non-uniformity of the barrier layer is between 1% and 5%.

19. The method of claim 15 wherein the first metal oxide layer comprises Praseodymium Calcium Manganese Oxide (PCMO).

20. The method of claim 15 wherein a thickness of the barrier layer is between 20 and 30 angstroms.
